(19) United States
(12) Patent Application Publication
(10) Pub. No.: US 2008/0280575 A1
(43) Pub. Date: Nov. 13, 2008

(54) Transmitter emission control

(75) Inventor: Mikko Pesola, Marynummi (FI)

Correspondence Address: SQUIRE, SANDERS & DEMPSEY L.L.P., 8000 TOWERS CRESCENT DRIVE, 14TH FLOOR, VIENNA, VA, 22182-6212, US

(73) Assignee: NOKIA CORPORATION

(21) Appl. No.: 11/896,205

(22) Filed: Aug. 30, 2007

(30) Foreign Application Priority Data
May 11, 2007 (FI) 20075343

(51) Int. Cl. H04B 1/04; G01R 19/00

(52) U.S. Cl. 455/127.1; 330/2

(57) ABSTRACT

The present invention relates to transmitter emission control. An apparatus is provided with a power amplifier and a power control part operatively connected to the power amplifier. The power control part is configured to receive an indication of a spectrum mask requirement and control supply power of the power amplifier on the basis of the indication of the spectrum mask requirement.

### FIELD

The present invention relates generally to radio devices and, more particularly, to transmitter emission control.

### BACKGROUND

In radio transmitters, a transmission signal, i.e. the signal being transmitted, is amplified by one or more amplifiers amplifying the transmission signal to a level suitable for transmission over an air interface to a radio receiver. The level of the transmission signal should be high enough to enable the radio receiver to decode information contained in the transmission signal. The transmission power level of a wireless terminal is typically dynamically adjusted based on power control information from a base station or an access point.

Spectrum mask, applied modulation method and corresponding adjacent channel power ratio (ACPR) requirements set the linearity requirement for a mobile terminal transmitter. A spectrum mask is generally a graphical representation of the required power distribution as a function of frequency for a modulated transmission. If the spectrum mask is more stringent, the transmitter needs to be more linear, and that consumes more power. Current cellular systems have only one global requirement for spectrum mask per each frequency band. However, there may be a need to provide multiple regional spectrum masks for a communications system. For instance, the IEEE has developed the IEEE 802.16 standard, the so-called WiMAX (Worldwide Interoperability for Microwave Access) standard, and the 802.20 standard. For a mobile WiMAX system (IEEE 802.16e), two separate regional spectrum masks for a 2.6 MHz frequency band have been planned. Thus a need exists to further improve transmitter emission control.

### SUMMARY

There is now provided an enhanced solution for transmitter emission control. This solution may be achieved by an apparatus, a method, a wireless communications apparatus, and a computer program medium as defined in the independent claims. Some embodiments of the invention are set forth in the dependent claims.

According to an aspect of the invention, an apparatus comprises a power amplifier for amplifying a signal for transmission over an air interface, and a power control part operatively connected to the power amplifier. The power control part is configured to receive an indication of a spectrum mask requirement. The power control part is configured to control supply power of the power amplifier on the basis of the indication of the spectrum mask requirement. Thus, at least some input to the power amplifier affecting the supply power of the power amplifier may be set in accordance with the current spectrum mask requirement.

In one embodiment, the power control part is configured to set supply voltage of the power amplifier on the basis of the spectrum mask requirement.

In another embodiment, the power control part is configured to set bias control for the power amplifier on the basis of the spectrum mask requirement.

Various features and advantages of the aspects of the invention will become apparent from the following description and accompanying drawings.

### BRIEF DESCRIPTION OF THE DRAWINGS

In the following, some embodiments will be described in further detail with reference to the accompanying drawings, in which

FIG. 1 is a block diagram comprising a power amplifier and a power management unit providing the power amplifier with power supply;

FIGS. 2a and 2b are block diagrams illustrating arrangements for transmitter power control;

FIG. 3 is a flow chart illustrating a method according to an embodiment; and

FIGS. 4a, 4b and 4c are diagrams illustrating WiMAX spectrum mask requirements.

### DETAILED DESCRIPTION OF EMBODIMENTS

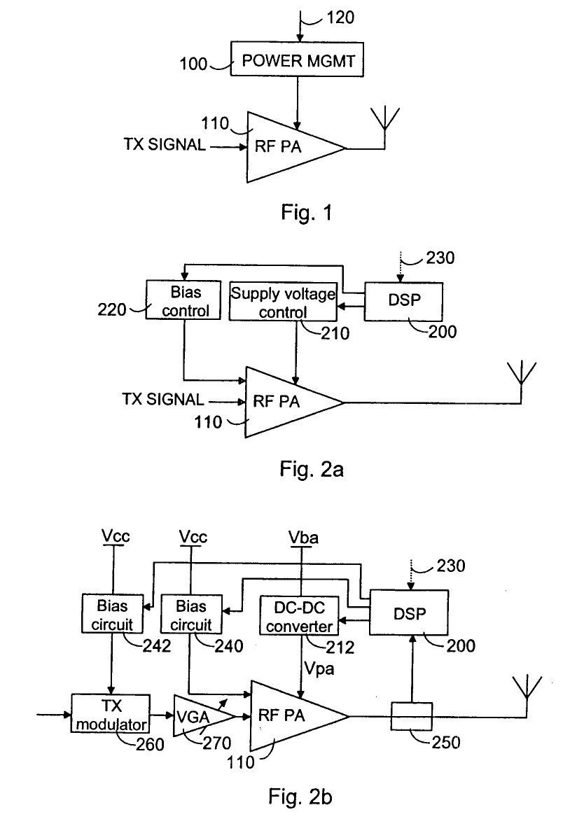

FIG. 1 illustrates a simplified radio transmitter arrangement comprising a power amplifier 110 and a power management portion 100 operatively connected to the amplifier 110. The power management portion 100 controls the direct current (DC) power supply of the amplifier 110 to achieve desired linearity, i.e. adjusts at least one input for the power amplifier affecting the supply power of the power amplifier 110 in accordance with a linearity requirement. Additionally, a transmission power output level may be controlled by the power management portion 100. Although the gain of the power amplifier 110 may be adjusted by the power management portion 100, typically the main adjustment to achieve a currently required RF transmission signal power level is carried out by gain control of a specific variable gain amplifier controlling the level of input signal to the power amplifier 110. The power management portion 100 may comprise an appropriate control circuitry controlled by a DSP processor, for instance.

The power management portion 100 is arranged to control the power supply to the power amplifier 110 in accordance with a spectrum mask requirement of the current operating environment. For this purpose, the power management portion 100 is arranged to receive an indication 120 of the spectrum mask requirement to be applied to the present operating environment. The indication of the spectrum mask requirement may be initially transmitted by an access network element, for instance an access point, an access network controller or a base station, with which a communications device, including the transmitter arrangement of FIG. 1, is currently signalling. However, the indication of the spectrum mask requirement may be submitted for the power management portion 100 in other ways, for instance determined, based on received network information, locally in the apparatus comprising the transmitter arrangement.

Hence, emission control of the transmitter can be further adapted in accordance with the current operating conditions, and adjusted in accordance with the current spectrum mask requirement. Now, in the case of several spectrum masks, instead of having the TX design based on the most stringent mask, the power supply to the power amplifier 110 can be adapted in accordance with the current spectrum mask requirement. Thus, power consumption can be reduced when transmitting in areas where more relaxed linearity is adequate, thereby resulting in extended operating time for battery-operated devices.

In one embodiment the power control part 100 is configured to adjust supply voltage of the amplifier 110 and/or bias control on the basis of a detected spectrum mask requirement (120).

In the following some further embodiments are illustrated. The description focuses particularly on some embodiments for the power management portion 100. For the sake of clarity, description of some other radio transmitter components, known per se, is omitted.

FIG. 2a illustrates an arrangement for radio transmitter power control, where a digital signal processor DSP 200 controls an amplifier control circuitry, represented by 210 and 220 in FIG. 2a, to control supply power to a power amplifier 110. In particular, the DSP 200 is arranged to receive an indication 230 of a currently required spectrum mask, and arrange the control accordingly. It is to be noted that a DSP is only one available option for implementing the control unit.

The DSP 200 is connected to a supply voltage control circuitry or unit 210 to control the supply voltage of the amplifier 110. By an appropriate control signal to the supply voltage control 210, the DSP 200 can control the unit 210 to provide an appropriate supply voltage level for the amplifier 110 to enable the output transmission signal of the amplifier 110 to meet the spectrum mask requirement. The supply voltage control unit 210 may be a DC-DC converter, i.e. a switching regulator, or any other device capable of scaling DC voltage to a desired voltage level. Based on the control signal from the DSP 200, the scaling factor may be adjusted as a response to changes in the spectrum mask requirement.

The DSP 200 is connected to the bias control circuitry 220 to control the bias current of the amplifier 110. By an appropriate control signal to the bias control circuitry 220, the DSP 200 can control the circuitry 220 to provide the amplifier 110 with an appropriate bias current to enable the output transmission signal of the amplifier 110 to meet the spectrum mask requirement.

Hence, the DSP 200 can be configured to output one or more control signals to achieve the desired output power characteristics so as to meet the spectrum mask requirement. Use of both bias control and supply voltage control enables further possibilities to define optimum operation points for each spectrum mask requirement. This embodiment of applying both bias control and supply voltage control is advantageous also in that the power amplifier current consumption is the highest.

The voltage and/or current control is defined such that the power level of the amplifier 110 is adequate so as to meet the currently required spectrum mask and to enable interference of the transmission signal to be prevented from substantially exceeding the levels defined in the spectrum mask. When an area with a more stringent spectrum mask is entered, the DSP 200 increases the supply power of the amplifier 110. When the transmitter is used in an area where a more relaxed spectrum mask is required, the DSP 200 controls the bias control circuitry 220 and/or the supply voltage control 210 such that the power consumption of the amplifier 110 is reduced.

FIG. 2b illustrates another embodiment, where the DSP 200 may control two bias circuits 240 and 242. The first bias circuit 240 is for the power amplifier 110 and the second bias circuit 242 is for a transmission modulator part 260.

A DC-DC converter 212 controls the supply voltage Vₚₐ of the power amplifier 110. An input of the DC-DC converter 212 may be connected to the power supply unit (a battery, for instance) to receive the power supply voltage V_{ba}. In accordance with the current spectrum mask requirement, the DSP 200 forms and outputs a control signal to the DC-DC converter 212. The DC-DC converter 212 may be adapted to scale the input power supply voltage V_{ba} according to the received control signal from the DSP 200. In an alternative embodiment, the DC-DC converter 212 may be configured to receive the indication of the spectrum mask requirement and comprise logic to determine an appropriate scaling factor from this received information.

The DSP 200 may control one or both of the bias circuits 240, 242 on the basis of the current spectrum mask requirement. In accordance with the current spectrum mask requirement, the DSP 200 forms and outputs a control signal(s) to the bias circuit(s) 240, 242.

Bias control based on the spectrum mask requirement may also be applied to the rest of the TX chain by the second bias circuit 242. In one embodiment, the DSP 200 is configured to define and output a control signal for the bias circuit 242 of the modulator unit 260 on the basis of the spectrum mask requirement, hence providing the possibility to adapt to the current spectrum mask requirements by adapting the modulator bias voltage/current.

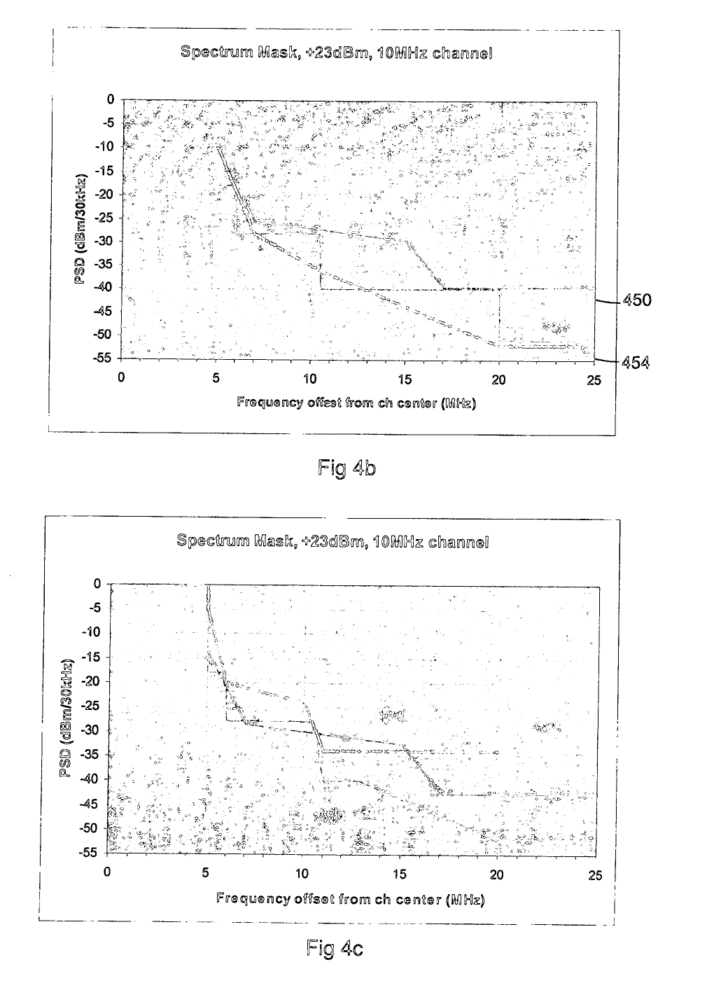

The implementation of the circuits 212, 240 and/or 242 is not limited to any specific circuitry implementation, but various circuit configurations may be applied for implementing these circuits controlled by a control unit (200) in accordance with the applied spectrum mask requirement. For instance, one such bias control circuit for a power amplifier is disclosed in U.S. Pat. No. 5,493,255, incorporated herein by reference, see FIG. 4. This document discloses a biasing circuit using a power level control signal for amplifier current control, and needs not to be described herein detail. Another such circuit is provided in U.S. Pat. No. 5,083,096, incorporated herein by reference, where a bias voltage control circuit is disclosed for controlling bias voltage of an amplifier.

FIG. 2b also indicates a power detection unit 250 providing feedback for the DSP 200 on power level at the output of the power amplifier 110. A variable gain amplifier VGA 270 is used for adjusting the input signal to the power amplifier 110 at an appropriate level such that the currently required RF power output level is not exceeded. The VGA 270 may be controlled by the DSP 200. In addition to the spectrum mask requirement, the DSP 200 may be arranged to adjust amplifier control in accordance with a received power control command. The DSP 200 may determine a control signal from received transmit power control commands defining the absolute transmission power of the radio transmitter. The transmit power control commands may be received from another radio transmitter communicating with the radio transmitter considered herein. The transmit power control commands may be part of a transmit power control procedure known in a wireless communications system.

In the following, some further embodiments are illustrated. These embodiments may be combined with each other, and with one or more of the above illustrated embodiments. Thus, even if reference is made to elements and in particular to the control portion 100 of FIG. 1, the features may well be applied to the configurations in FIGS. 2a and 2b and to one or more of the controlling elements thereof, for instance.

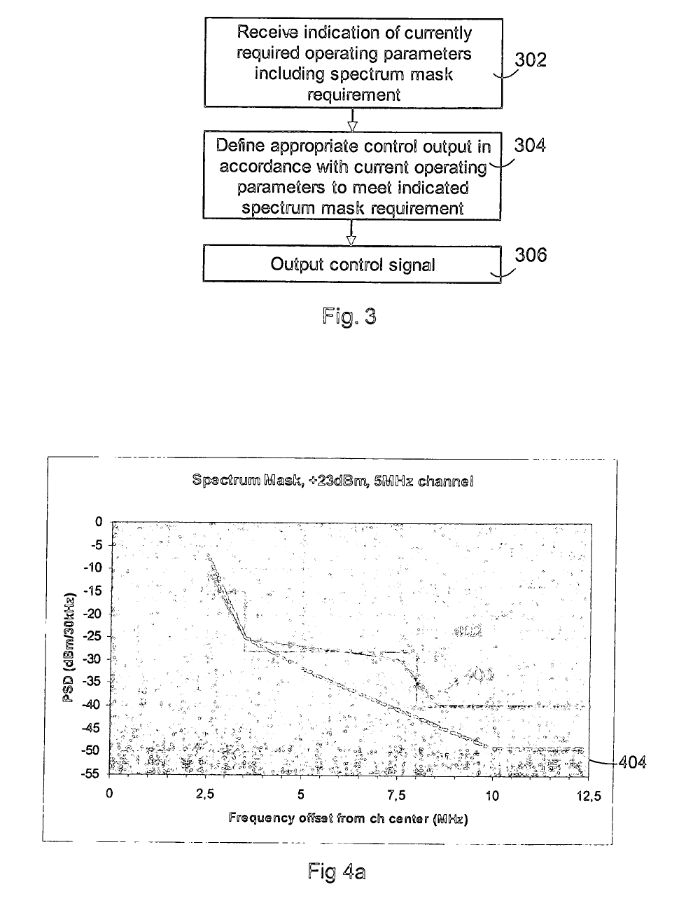

FIG. 3 illustrates a method according to an embodiment for transmission power control. The steps of FIG. 3a may be implemented by a control unit(s) in the power management portion 100, for instance by the DSP 200 of FIG. 2a or 2b. In one embodiment, the steps are implemented by software executed in a processor.

In step 300, an indication of currently required operating parameters, including a required spectrum mask, is received. Other operating parameters include an RF signal power level and a modulation method, for instance. In step 302 appropriate values affecting the power amplifier supply power are defined to meet the current operating requirements. An appropriate control output or signal, or a plurality of such control outputs or signals, is defined in accordance with the current operating parameters, i.e. operating point, to meet the local operation requirements including the required spectrum mask. In step 304, the control signal is outputted, i.e. the power amplifier supply power control circuitry is controlled.

In one embodiment, the indication of the spectrum mask requirement is indicated as a value in a signalling message transferred between radio communications devices. For instance, a base station, an access point, or a controller for a radio access or base station network may be configured to define such signalling message comprising the spectrum mask requirement value, and transmit the signalling message to a terminal device. The spectrum mask requirement value is detected from such a signalling message and may be stored. The delivery and application of this indication is not limited to any specific type of indication or coding method.

In one embodiment, the indication of the spectrum mask requirement is generated on the basis of a channel identifier. A controller of a communications device comprising the present radio transmitter arrangement may be configured to receive a channel identifier, such as a channel number, in a received signal indicative of a transmission channel to be used. Based on this channel identifier, the controller defines the indication of the spectrum mask requirement. Thus, it is not necessary to transmit specific mask requirement information over the radio interface, but specific mask requirements may be associated with channels by pre-stored mask requirement-channel identifier mapping information. The indication of the spectrum mask requirement is delivered from the controller to the power management portion 100, such as the DSP 200, which then arranges control procedures on the basis of the received indication, as already illustrated. In an alternative embodiment, the power management portion 100 is arranged to determine or detect the spectrum mask requirement on the basis of received network or channel information, such as a channel identifier, and thus implicitly receive the indication of the spectrum mask requirement in the form of the network or channel information.

The definition of the appropriate control affecting the supply power on the basis of the received spectrum mask indication may be implemented in various ways, some of which are illustrated below. In one embodiment, the control is arranged such that the one or more control inputs or values are predefined in the power management portion 100 as associated with a mask requirement. Hence, there may be a pre-stored list of entries formed by a spectrum mask requirement indicator and associated input(s) or value(s). Based on the received indicator, the power management portion 100 detects an entry comprising the same indicator, and controls the amplifier control circuitry in accordance with the associated input(s) or value(s) to set appropriate supply power for the power amplifier. In a further embodiment, supply voltage and bias values are predefined for each set of operating parameters, such as a spectrum mask including the channel width, modulation method, and power level.

The control parameters or values for each operating point may be stored in look-up tables. In another embodiment, the value(s) are calculated from the parameters using a formula. Different combinations of these options are also possible. For instance, a look-up table may be applied to power levels and an offset value may be applied to a spectrum mask and modulation.

The mask requirements may be different for channels having different channel widths. In one embodiment, the power management control portion 100 is adapted to control the power amplifier supply voltage and/or bias on the basis of an indication of the channel width, which may be one of the indicators applied in step 300. Thus, a locally applied mask requirement, for instance one in the United States, may involve a specific mask requirement for each channel width, and predefined value(s) associated with the currently applied channel width are selected for power supply control.

In one embodiment, the power control based on a spectrum mask requirement is implemented in a WiMAX transmitter. In the following an embodiment for WiMAX communications is further explained. However, it is to be noted that the application of the present embodiments is not limited to any specific radio system, but may be applied to a type of a system where no need to apply two or more spectrum masks exists. Some examples of such systems include other wireless broadband wide area networks (WANs), local area networks, or metropolitan area networks (MANs), but the embodiments could also be applied to transmitters for cellular systems, such as the long-term evolution of 3GPP radio technology (LTE).

The IEEE 802.16 standard is also known as the IEEE Wireless Metropolitan Area Network, delivering performance comparable to a traditional cable or DSL (Digital Subscriber Line), and is considered to provide the “last mile” connectivity at high data rates. WiMAX applies OFDM (Orthogonal Frequency Division Multiplexing) technology, adaptive modulation and error correction. In a mobile WiMAX system (IEEE 802.16e), the working assumption in standardization is to have two separate regional spectrum masks for a 2.6 GHz frequency band.

In one embodiment, the device comprising the power management portion 100 is configured to control the transmission power to adapt to at least two WiMAX spectrum masks, as required by the local WiMAX network. The spectrum mask requirement may be transmitted in a control message from a WiMAX base station (BS) to a WiMAX subscriber station (SS) or a mobile station (MS), and a control unit 100, 200 of the SS/MS controls the transmitter power in accordance with this received information, for instance by the configuration illustrated in FIG. 2b.

FIGS. 4a and 4b illustrate WiMAX spectrum masks currently being planned for 5 MHz and 10 MHz channels, respectively. In FIG. 4a, the curve 400 indicates a spectrum mask requirement of a European EN 302544 draft definition, the curve 402 indicates a spectrum mask requirement of US Federal Communications Commission (FCC), and the curve 404 indicates a spectrum mask requirement of Japanese draft definition.

In FIG. 4b, the curve 450 indicates a spectrum mask requirement of the European EN 302544 draft definition, the curve 452 indicates a spectrum mask requirement of the FCC (FCC part 27), and the curve 454 indicates a spectrum mask requirement of the Japanese draft definition.

FIG. 4c illustrates one further option of WiMAX spectrum masks for a 10 MHz channel for a 2.6 GHz band. The curve 480 indicates a spectrum mask requirement of the European draft EN 302544 definition, the curve 482 indicates a spectrum mask requirement of the WiMAX Forum, and curve 484 indicates a spectrum mask requirement of the UK Authority Ofcom. For more details on such mask requirements, reference is made to Section 9 of Ofcom specification “Award of available spectrum: 2500-2690 MHz, 2010-2025 MHz, 2290-2300 MHz”, Consultation, publication date 11 Dec. 2006, 297 pages, and FCC regulations, part 27.53 on emission limits, 47CFR27.53, revised as of Oct. 1, 2005, pages 303-308, available at http://www.access.gpo.gov/nara/cfr/waisidx_{—}05/47cfr27_{—}05.html. It is to be noted that the above spectrum masks may be subject to change, and the above aspects may be applied for adaptation between future spectrum mask requirements.

In one embodiment, the power management portion 100 is configured to selectively control the amplifier 110 to output an RF signal essentially meeting at least two of the spectrum mask requirements 400, 402, 404 for a 5 MHz channel, and/or the spectrum mask requirements 450, 452, 454, and 480 to 484 for a 10 MHz channel.

In one embodiment, the power control part 100 is configured to selectively adjust the supply of the power amplifier due to a change between a first mask requirement and a second mask requirement in response to at least a predefined difference existing between the first mask requirement and the second mask requirement at a distance from the channel center. Hence, if the difference between the mask requirements exceeds a predetermined limit, the supply power of the power amplifier is adjusted when a change takes place between first and second mask requirements. For instance, at least 5 dBm or dB relative to a maximum power spectral density difference (dBr) may be required. However, the application is not limited to any specific minimum value, but other values may be applied; for instance at least an 8 dBr/dBm or a 10 dBr/dBm difference may be required. In this embodiment, it is not necessary to change the supply voltage and/or bias control every time the mask requirement is changed, and the same supply voltage and/or bias values may be applied to more than one spectrum mask.

In a further embodiment, a minimum difference may be required at a predetermined distance or distance range from the center of a channel. For instance, the minimum difference may be required for at least a 5 MHz distance from the channel center, or in the area between 2.5 MHz to 20 MHz from the center of the channel.

As already illustrated, the control output may be adjusted dynamically in response to a change in the operating environment. The need for a power amplifier power supply adjustment may be checked every time a change in one or more of the operating parameters is detected. For instance, first power amplifier supply voltage and bias values are applied to an operating point with properties: FCC mask in a 10 MHz channel, QPSK modulation and +23 dBm output power. When the transmitter changes to FCC 5 MHz, the mask and all other parameters stay the same, the power management portion 100 may control a decrease in the power amplifier supply voltage, and possibly also the bias current, since the linearity requirement is slightly smaller for this mask.

The mask requirement may need to be fulfilled only in the edges of a frequency block allocated for an operator. For instance, for a 6×5 MHz frequency block, the mask requirement may need to be fulfilled only in the lowest and highest channel. In one embodiment, the power management control portion 100 is adapted to control the supply power of the power amplifier on the basis of an indication of the applied channel. In particular, the power management control portion 100 may be adapted to control the use of first mask specific operating voltage and/or bias value(s) for meeting the mask requirement only when operating on these edge channels, and use second value(s) producing a more relaxed spectrum mask in the remaining channels of the block. Hence, power consumption may be further reduced.

According to an aspect, power supply to a power amplifier may be controlled based on generally any of at least one indicator for an out-of-band emission property or requirement applied to the current operating environment of the transmitter. In one embodiment, the above illustrated mask requirement is applied as such a property. In another embodiment, the power supply of the power amplifier 100 is controlled based on a limit or condition currently being applied to spurious emissions. The applied spurious emissions limit may be detected in various ways, such as by utilizing an information element detected in received information indicating the current operating area and prestored information on the limit applied to this area.

At least some of the above illustrated embodiments (excluding FIGS. 4a to 4c) may also be applied to the present embodiment of controlling the power amplifier power supply on the basis of the spurious emissions limit (instead of the specific mask requirement). For instance, the embodiments of FIGS. 1 to 3 may be applied. The power amplifier supply voltage and/or bias control may be adapted on the basis of the spurious emissions limit.

A spurious emissions limit may be applied to offset frequencies larger than a spectrum mask requirement. For instance, ETSI specifications in Europe have a spectrum mask requirement up to offset that equals 2.5 times the channel bandwidth. Beyond that offset the spurious emissions limit applies. The embodiment applying spurious emissions limit may be used in addition to other controlling input(s), such as the mask requirement. Thus, it is possible to address a number of out-of-band emission related requirements by appropriately adjusting the power amplifier supply. For instance, the power amplifier power supply may be adapted to meet the future ETSI requirements for 2.6 GHz band (currently being drafted under reference EN 302 544).

In some cases, the spurious emissions limit may be more stringent than the spectrum mask. For instance, in Europe the general spurious emissions limit is −30 dBm/MHz for most frequencies but a section from 2620 MHz to 2690 MHz has an additional limit of −43 dBm/MHz. In one embodiment, the control may be adjusted in dependence on the frequency range applied, for instance to meet the European limit.

The above-illustrated embodiments may be implemented in a power management device included in a radio transmitter. The radio transmitter may be a battery-operated mobile radio transmitter, for instance one for a mobile communication device communicating with a radio access network of a mobile telecommunication system. As already indicated, the embodiments may be implemented in a transmitter and a wireless communications device adapted to WAN communications, and in a further embodiment for WiMAX communications.

The control means (100, 200) described above may be implemented by various means. For example, the control unit outputting control signals on the basis of the spectrum mask requirement may be implemented in hardware (one or more devices), firmware (one or more devices), software (one or more modules), or combinations thereof. For a hardware implementation, the control unit(s) (100; 200) used for power control may be implemented within one or more application specific integrated circuits (ASICs), digital signal processors (DSPs), digital signal processing devices (DSPDs), programmable logic devices (PLDs), field programmable gate arrays (FPGAs), processors, controllers, micro-controllers, microprocessors, other electronic units designed to perform the functions described herein, or a combination thereof. For firmware or software, implementation can be through modules (e.g. procedures, functions, and so on) that perform the functions described herein. The software codes may be distributed by a distribution medium, stored on a memory unit and executed by the processors. The memory unit may be implemented within the processor or external to the processor, in which case it can be communicatively coupled to the processor via various means as is known in the art. Additionally, components of systems described herein may be rearranged and/or complimented by additional components in order to facilitate achieving the various aspects, goals, advantages, etc., described with regard thereto, and are not limited to the precise configurations set forth in a given figure, as will be appreciated by one skilled in the art.

The accompanying drawings and the related description are only intended to illustrate the present invention. Different variations and modifications of the invention will be apparent to those skilled in the art, without departing from the scope of the invention defined in the appended claims. Different features may thus be omitted, modified or replaced by equivalents.

1. An apparatus, comprising:
a power amplifier for amplifying a signal for transmission over an air interface; and
a power control part operatively connected to the power amplifier, wherein
the power control part is configured to receive an indication of a spectrum mask requirement, and
the power control part is configured to control supply power of the power amplifier on the basis of the indication of the spectrum mask requirement.

2. The apparatus of claim 1, wherein the power control part is configured to set the supply voltage of the power amplifier on the basis of the spectrum mask requirement.

3. The apparatus of claim 2, wherein the power control part comprises a control unit and a supply voltage control unit for setting the supply voltage of the power amplifier,
the control unit is configured to receive the indication of the spectrum mask requirement,
the control unit is configured to output a control signal to the supply voltage control unit on the basis of the indication of the spectrum mask requirement, and
the supply voltage control unit is configured to set the supply voltage of the power amplifier in accordance with the control signal from the control unit.

4. The apparatus of claim 1, wherein the power control part is configured to set bias control of the power amplifier on the basis of the spectrum mask requirement.

5. The apparatus of claim 4, wherein the power control part comprises a control unit and a bias control circuit for setting the bias current,
the control unit is configured to receive the indication of the spectrum mask requirement from another transmitter,
the control unit is configured to output a control signal to the bias control circuit on the basis of the indication of the spectrum mask requirement, and
the bias control circuit is configured to control the bias current of the power amplifier in accordance with the control signal from the control unit.

6. The apparatus of claim 5, wherein the control unit is configured to output a control signal on the basis of the spectrum mask requirement for a further bias control circuit to set bias control of a modulator.

7. The apparatus of claim 1, wherein the power control part is configured to control the power amplifier of a WiMAX transmitter to output RF signals to meet at least two mask requirements of a WiMAX system.

8. The apparatus of claim 7, wherein the power control part is configured to selectively adjust the supply of the power amplifier due to a change between a first mask requirement and a second mask requirement in response to at least 5 dBm or dB relative to a maximum power spectral density difference (dBr) between the first mask requirement and the second mask requirement at some distance from a channel center.

9. The apparatus of claim 7, wherein the power control part is configured to adjust the supply of the power amplifier due to a change between a first mask requirement and a second mask requirement in response to at least one of the following conditions existing between the first mask requirement and the second mask requirement: at least a 5 dBm difference between the mask requirements at 2.5 MHz or more frequency offset from the center of a 5 MHz channel, at least a 5 dBm difference between the mask requirements at 5 MHz or more frequency offset from the center of a 10 MHz channel, at least an 8 dBm difference between the mask requirements at a point between 2.5 MHz to 20 MHz frequency offset from the center of a 5 MHz channel, at least a 10 dBm difference between the mask requirements at a point between 5 MHz to 20 MHz frequency offset from the center of a 10 MHz channel.

10. The apparatus of claim 1, wherein the power control part is configured to detect a desired channel width and control the supply power of the power amplifier in accordance with the spectrum mask required for the detected channel width.

11. The apparatus of claim 1, wherein the power control part is configured to apply first values to control the supply power of the power amplifier for channels in an edge of a frequency block and second values for the remaining channels.

12. The apparatus of claim 1, wherein the apparatus is configured to generate the indication of the spectrum mask requirement on the basis of a channel identifier.

13. The apparatus of claim 1, wherein the apparatus is configured to control the power supply of the power amplifier on the basis of a limit or condition currently being applied to spurious emissions.

14. A method for amplifier control, the method comprising:
receiving an indication of a spectrum mask requirement;
specifying an appropriate control output in accordance with the received spectrum mask requirement; and
controlling supply power of a power amplifier of the transmitter on the basis of the control output.

15. The method of claim 14, wherein transmission bias current and/or supply voltage to the amplifier is adapted on the basis of the indication of the spectrum mask requirement.

16. A wireless communications apparatus comprising:
an apparatus comprising
a power amplifier for amplifying a signal for transmission over an air interface; and
a power control part operatively connected to the power amplifier, wherein
the power control part is configured to receive an indication of a spectrum mask requirement, and
the power control part is configured to control supply power of the power amplifier on the basis of the indication of the spectrum mask requirement.

17. The wireless communications apparatus of claim 18, wherein the apparatus is configured to control a transmission bias current and/or supply voltage value to the amplifier on the basis of the indication of the spectrum mask requirement.

18. An apparatus comprising:
means for receiving an indication of a spectrum mask requirement, and
means for controlling supply voltage and/or bias current of a power amplifier on the basis of the indication of the spectrum mask requirement.

19. The apparatus according to claim 19, wherein the communications apparatus is a WiMAX radio apparatus.

20. A computer program embodied on a computer readable medium, the computer program comprising program code for executing a computer process for controlling a controller to:
receive an indication of a spectrum mask requirement;
specify an appropriate control output in accordance with the received spectrum mask requirement; and
control supply power of a power amplifier of a transmitter on the basis of the control output.

21. The computer program medium according to claim 20, comprising computer program code for controlling a transmission bias current and/or supply voltage value to the amplifier on the basis of the indication of the spectrum mask requirement.
